(19) United States
(12) Patent Application Publication
(10) Pub. No.: US 2008/0106441 A1
(43) Pub. Date: May 8, 2008

(54) Keyboard in the form of a carpet or a mat

(76) Inventor: Wayne Gen Chiang, Douglaston, NY (US)

Correspondence Address: TROXELL LAW OFFICE PLLC, SUITE 1404, 5205 LEESBURG PIKE, FALLS CHURCH, VA, 22041, US

(21) Appl. No.: 11/593,153

(22) Filed: Nov. 6, 2006

(51) Int. Cl. H03M 11/00

(52) U.S. Cl. 341/22

(57) ABSTRACT

A keyboard in the form of a carpet or a mat, comprising: a main body, a plurality of keys disposed within the main body, marks corresponding to the keys disposed on the surface of the main body for identifying key positions, an electrical circuit board disposed within the main body, and a connection device for connecting with a usual computer. Users can input data into the computer via the keyboard by using their feet alone.

### BACKGROUND OF THE INVENTION

1. Field of the Invention

The present invention relates to a keyboard in the form of a carpet or a mat, especially to a keyboard in the form of a carpet or a mat, which has a main body, a plurality of keys, marks corresponding to the keys, an electrical circuit board, and a connection device.

2. Description of the Prior Art

There are many different kinds of input devices, among them a keyboard may be one used most commonly. Sometimes a keyboard may be used with the help of a mouse, a track ball, a joystick, or a handwriting recognition system. However, the common demand of the above devices is that a user needs to have manual dexterousness. And for handicapped people—especially for those with upper limb disability, it will be hard or even impossible to use such devices to input data into computers.

With the technological development, the use of a speech recognition system provides an alternative way for people with upper limb disability to input data into computers. It is the most simple and direct way to use a speech recognition system to operate input process. All a user has to use is just a microphone or other like devices without the need of a keyboard or other auxiliary tools demanded by the input devices using hands. However, background inference and the pronunciation difference of people make it harder to input data into a computer precisely and correctly.

Recently, some keyboards used by feet emerge in the market. However, These keyboards are mainly used for entertainment purpose and not designed to connect with a usual computer for data input. Besides, the keys are usually protruding from the surface of those keyboards used by feet so that those keyboards are not comfortable for trampling thereon and not suitable for data input owing to the much longer duration for data input than that just for entertainment.

### SUMMARY OF THE INVENTION

The primary object of the present invention is to provide a keyboard in the form of a carpet or a mat, which can be used without the need of hands or a speech recognition system.

Another object of the present invention is to provide a keyboard in the form of a carpet or a mat having a flat and comfortable surface for trampling thereon.

Still another object of the present invention is to provide a keyboard in the form of a carpet or a mat having a connection device for connecting with a usual computer.

Still another object of the present invention is to provide a keyboard in the form of a carpet or a mat that can be used by feet alone for fitness and physical exercises.

In order to achieve these above objects, the present invention provides a keyboard in the form of a carpet or a mat, comprising a main body, a plurality of keys disposed within the main body, an electrical circuit board disposed within the main body, and a connection device, so that a user can operate the keyboard by feet alone to input data into a computer, wherein the main body is made of material like a carpet or a mat and a flat and comfortable surface is provided by disposing a plurality of keys within the main body so that a user can comfortably trample on the keyboard.

The following detailed description, given by way of examples and not intended to limit the invention solely to the embodiments described herein, will best be understood in conjunction with the accompanying drawings.

### BRIEF DESCRIPTION OF THE DRAWINGS

FIG. 1 is a perspective view that shows an embodiment of a keyboard in the form of a carpet or a mat of the present invention.

FIG. 1A shows a locally enlarged part of the keyboard in the FIG. 1.

FIG. 2 shows the using state of the keyboard in FIG. 1.

FIG. 3 shows the keyboard in FIG. 1 connected with a usual computer.

### DETAILED DESCRIPTION OF THE PREFERRED EMBODIMENTS

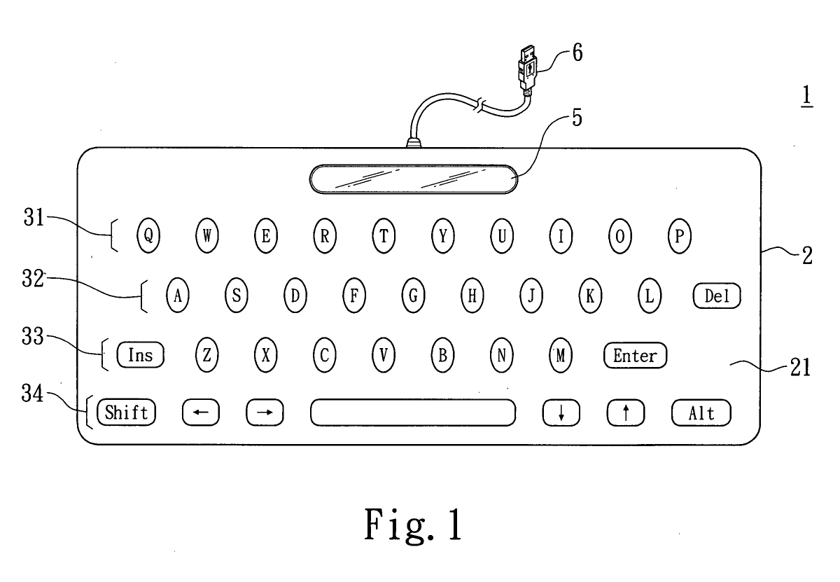

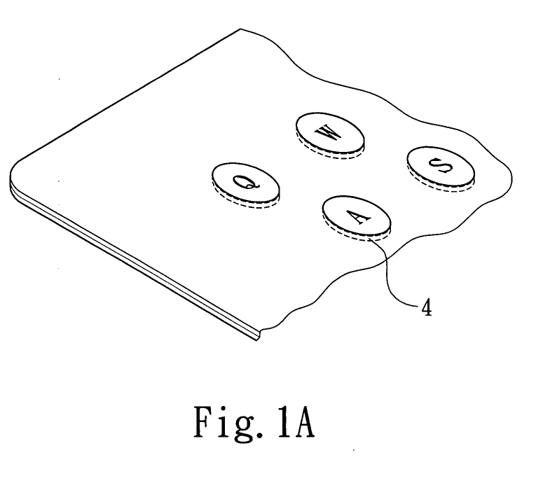

Referring to FIGS. 1 and 1A, FIG. 1 shows an embodiment of a keyboard 1 in the form of a carpet or a mat according to the present invention and FIG. 1A shows a locally enlarged part of the keyboard in the FIG. 1, wherein the keyboard 01 comprises a main body 2, a plurality of keys 4 disposed within the main body 2, an electrical circuit board (not shown) disposed within the main body 2, and a USB connector 6.

The present invention provides a keyboard 1 which can be used by feet alone, wherein the main body 2 is made of material like a carpet or a mat within which a plurality of keys 4 are disposed so that a user can trample comfortably on the flat surface 21 of the main body 2. The keys 4 are divided into four rows. In the order from left side to right side, the first row includes keys of alphabets Q, W, E, R, T, Y, U, I, O, P; the second row includes keys of A, S, D, F, G, H, J, K, L and a Delete (Del); the third row includes keys of a Function (Fn), alphabet Z, X, C, V, B, N, M, and an Enter; the forth row includes keys of a Shift, a Left arrow, a Right arrow, a Space, a Up arrow, a down arrow, and a Control/Alter (Ctrl/Alt). The present invention select least and most commonly used keys to achieve the greatest effect. Besides, the function of the keys is principally the same with one of the keys in a usual keyboard used by fingers so that a user will be more acquainted with the locations of the keys.

Moreover, the Function key as mentioned above is used to switch some predetermined alphabet keys to Number keys. In the embodiment of the present invention, when the Function key is trampled, some predetermined alphabet keys will represent their corresponding numbers, wherein Z represents 1, X represents 2, C represents 3, S represents 4, D represents 5, F represents 6, W represents 7, E represents 8, R represents 9, A represents 0. If the Function key is trampled once again, the predetermined alphabet keys will again represent their original meaning.

Furthermore, users can trample on each mark by using their feet without stepping on other keys via the keys' arrangement where each key are arranged longitudinally and transversely to mutually cross each other so that space will be provided between the keys for users to imposing their feet thereon.

And a plurality of marks is arranged on the surface of the main body 2 for indicating the locations of their corresponding keys 4 within the main body 2. These marks include alphabet key marks, Enter key mark, Space key mark, Shift key mark, Function key mark, Direction arrow key marks, Delete key mark, and Control/Alter key mark, wherein a first row mark 31 indicates the keys arranged in the first row, a second row mark 32 indicates the keys arranged in the second row, a third row mark 33 indicates the keys arranged in the third row, and a forth row mark 34 indicates the keys arranged in the forth row. Alphabet key marks are oval shape and in the size of a foot, and other key marks are oblong and in the size larger than that of a foot.

Besides, an indicator 5 is further provided above the first row mark 31 on the surface 21 of the main body and is electrically connected with the keys. When a user operates the keyboard 1 and the key trampled is indeed activated to form an effective circuit, the indicator 5 will blink once. And a USB connector 6 is further provided on one side of the main body 2, which can be in connection with a usual computer and thus gain power supply form the computer.

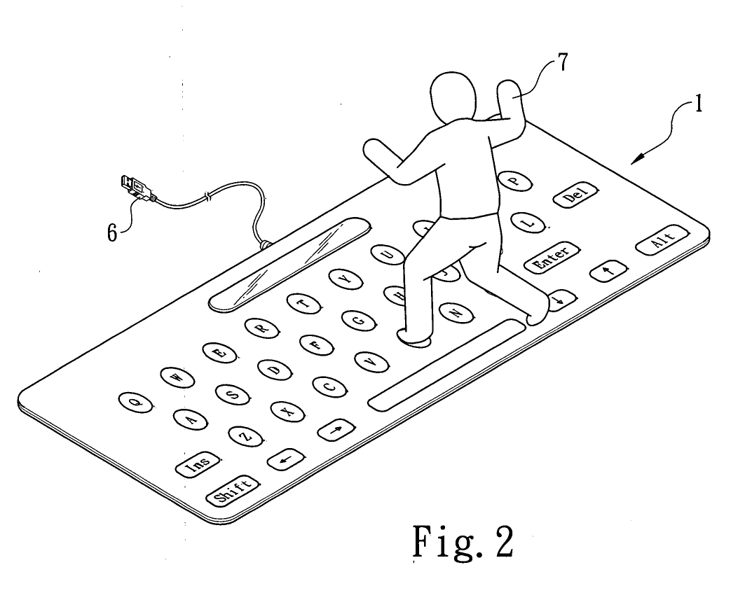

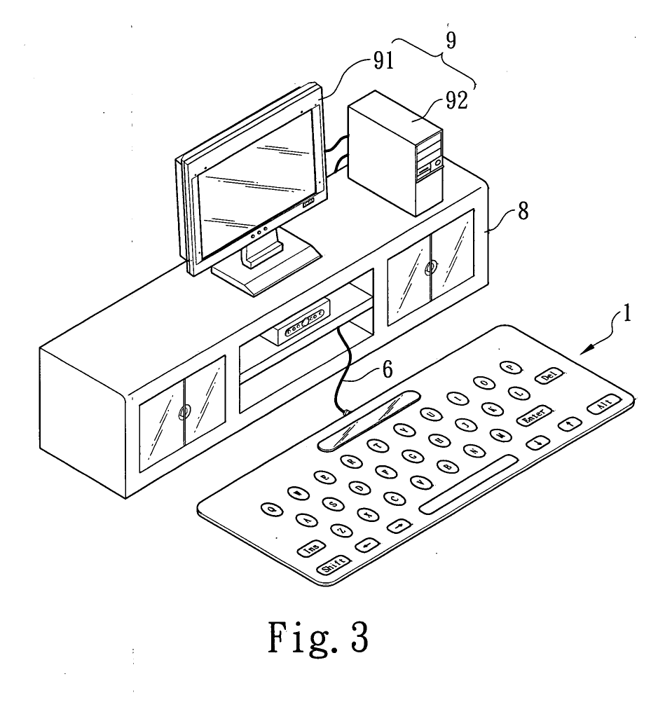

FIG. 2 shows the using state of the keyboard 1 in FIG. 1, which can be used by a user 7 with feet alone. And FIG. 3 shows the keyboard 1 in FIG. 1, which is in connection with a usual computer 9 having a display 91 and a main frame 92 on a TV bench 8.

Accordingly, as disclosed in the above description and attached drawings, the present invention can provide a keyboard in the form of a carpet or a mat which can be operated by feet alone, has a flat and comfortable surface for trampling thereon, and can be in connection with a usual computer. It is new and can be put into industrial use.

While the invention has been described with reference to certain embodiments, it will be understood by those skilled in the art that various changes may be made and equivalents may be substituted without departing from the scope of the present invention.

What is claimed is:

1. A keyboard in the form of a carpet or a mat, comprising:
a main body having a comfortable and flat surface;
a plurality of keys disposed within the main body;
marks corresponding to the keys disposed on the surface of the main body for indicating the keys;
an electrical circuit board disposed within the main body; and
a connection device in connection with a usual computer.

2. The keyboard in the form of a carpet or a mat as claimed in claim 1, wherein each of the marks corresponding to the keys is in the size of an average foot.

3. The keyboard in the form of a carpet or a mat as claimed in claim 1, wherein a plurality of keys include
twenty six alphabet keys;
at least one Enter key;
at least one Space key;
at least one Shift key; and
at least one Function key.

4. The keyboard in the form of a carpet or a mat as claimed in claim 3, wherein the function key is used to switching some predetermined alphabet keys to Number keys.

5. The keyboard in the form of a carpet or a mat as claimed in claim 3, wherein the keys further includes at least one Direction-Arrow key.

6. The keyboard in the form of a carpet or a mat as claimed in claim 3, wherein the keys further includes a Delete key and a Control/Alter keys.

7. The keyboard in the form of a carpet or a mat as claimed in claim 3, wherein the keys are arranged longitudinally and transversely to mutually cross each other.

8. The keyboard in the form of a carpet or a mat as claimed in claim 1, wherein at least one indicator is further provided on the surface of the main body and will blink when a key is trampled to be activated.

9. The keyboard in the form of a carpet or a mat as claimed in claim 1, wherein the connection device is a USB connector used for connecting with a usual computer.
